(19) United States
(12) Patent Application Publication
(10) Pub. No.: US 2021/0375971 A1
(43) Pub. Date: Dec. 2, 2021

(54) SENSOR DEVICE, PRODUCTION METHOD THEREFOR, AND ELECTRONIC EQUIPMENT

(71) Applicant: Sony Semiconductor Solutions Corporation, Kanagawa (JP)

(72) Inventor: Hiroshi TAYANAKA, Kanagawa (JP)

(21) Appl. No.: 17/286,661

(22) PCT Filed: Oct. 11, 2019
(86) PCT No.: PCT/JP2019/040172

§ 371 Date: Apr. 19, 2021

(30) Foreign Application Priority Data
Oct. 26, 2018 (JP) 2018-202191

(51) Int. Cl. H01L 27/146

(52) U.S. Cl. CPC H01L 27/14632; H01L 27/1462; H01L 27/14687; H01L 27/14627; H01L 27/1463; H01L 27/14621

(57) ABSTRACT

The present disclosure relates to a sensor device, a production method therefor, and electronic equipment that enable achievement of improvement of a property of receiving light.

The sensor device includes a semiconductor substrate including a first face on which light is incident and a second face facing opposite to the first face, plural pixels each including a photoelectric conversion region used for performing photoelectric conversion and disposed in the semiconductor substrate, and plural grooves disposed on the first face of each of the pixels. Further, in cross-sectional view, the grooves each include a first groove side face disposed along a vertical direction relative to the second face of the semiconductor substrate and a second groove side face disposed in a direction different from the vertical direction. The present technology can be applied to, for example, a CMOS image sensor.

### TECHNICAL FIELD

The present disclosure relates to a sensor device, a production method therefor, and electronic equipment, and in particular, relates to a sensor device, a production method therefor, and electronic equipment that are configured to enable achievement of improvement of a property of receiving light.

### BACKGROUND ART

Various kinds of electronic equipment having an image sensing function, such as a digital still camera and a digital video camera, conventionally employ a solid-state image sensing device such as a CCD (Charge Coupled Device) or CMOS (Complementary Metal Oxide Semiconductor) image sensor. Such a solid-state image sensing device is, for example, configured such that plural pixels are arranged in an array on its light receiving face that receives light from an object and that improvement of light collection for each of the pixels and prevention of reflection of light at the light receiving face have been attempted, in order to enable the light to be received favorably.

For example, in PTL 1, there is disclosed a solid-state image sensing device having a structure formed with a light collection lens which is configured to enable collection of light toward the center portion of pixels of infrared light detection sections by gradually changing, for each of stages, the radius of curvature toward the periphery from the center portion of the pixels.

Further, in PTL 2, there is disclosed a solid-state image sensing device having a structure including a semiconductor substrate in which a photoelectric conversion section is formed for each of plural pixels and an antireflection structure that is disposed on the side of a light incident face on which incident light toward the semiconductor substrate is incident and that has a structure in which plural kinds of protrusions having mutually different heights are formed. In the solid-state image sensing device, the antireflection structure is formed by performing a process of excavating the light incident face of the semiconductor substrate in a manner dividing the process into plural steps according to mutually different conditions for the process. Further, the antireflection structure has a structure in which, between first protrusions having a predetermined height, a second protrusion having a height lower than the height of the first protrusions is formed.

### CITATION LIST

### Patent Literature

[PTL 1]

Japanese Patent Laid-open No. Sho 61-145861

[PTL 2]

Japanese Patent Laid-open No. 2015-220313

### SUMMARY

### Technical Problems

Meanwhile, the solid-state image sensing devices disclosed in PTL 1 and PTL 2 have a concern that the light is scattered to the left and right to worsen color mixing between adjacent pixels, and are thus deemed to be capable of being used only in capturing monochromatic light such as infrared rays. In particular, for the structure of the solid-state image sensing device disclosed in PTL 2, implementing light collection such as that of a Fresnel lens is not assumed, and the light is collected by using an on-chip lens disposed for each of pixels. Thus, it has been difficult to achieve sensitivity enhancement and height reduction.

The present disclosure has been made in view of such situations and is intended to enable achievement of improvement of the property of receiving light.

### Solution to Problems

A sensor device according to an aspect of the present disclosure includes a semiconductor substrate including a first face on which light is incident and a second face facing opposite to the first face, plural pixels each including a photoelectric conversion region used for performing photoelectric conversion and disposed in the semiconductor substrate, and plural grooves disposed on the first face of each of the pixels, and, in cross-sectional view, the grooves each include a first groove side face disposed along a vertical direction relative to the second face of the semiconductor substrate and a second groove side face disposed in a direction different from the vertical direction.

A production method according to an aspect of the present disclosure is a production method for a production apparatus that produces a sensor device including a semiconductor substrate including a first face on which light is incident and a second face facing opposite to the first face, plural pixels each including a photoelectric conversion region used for performing photoelectric conversion and disposed in the semiconductor substrate, and plural grooves disposed on the first face of each of the pixels, the production method including forming, by the production apparatus, the grooves such that, in cross-sectional view, the grooves each include a first groove side face disposed along a vertical direction relative to the second face of the semiconductor substrate and a second groove side face disposed in a direction different from the vertical direction.

Electronic equipment according to an aspect of the present disclosure includes a sensor device including a semiconductor substrate including a first face on which light is incident and a second face facing opposite to the first face, plural pixels each including a photoelectric conversion region used for performing photoelectric conversion and disposed in the semiconductor substrate, and plural grooves disposed on the first face of each of the pixels, and, in cross-sectional view, the grooves each include a first groove side face disposed along a vertical direction relative to the second face of the semiconductor substrate and a second groove side face disposed in a direction different from the vertical direction.

According to an aspect of the present disclosure, in cross-sectional view, each of plural grooves includes a first groove side face disposed along a vertical direction relative to a second face of a semiconductor substrate and a second groove side face disposed in a direction different from the vertical direction.

### BRIEF DESCRIPTION OF DRAWINGS

FIG. 1 is a diagram illustrating a configuration example of a first embodiment of a pixel to which the present technology is applied.

FIG. 2 is a diagram illustrating a Fresnel structure of the pixel of FIG. 1 in an enlarged manner.

FIG. 3 is a diagram illustrating a first configuration example of an image sensing device including the pixel of FIG. 1.

FIG. 4 is a diagram illustrating a configuration example of a second embodiment of the pixel to which the present technology is applied.

FIG. 5 is a diagram illustrating a Fresnel structure of the pixel of FIG. 4 in an enlarged manner.

FIG. 6 is a diagram illustrating a second configuration example of an image sensing device including the pixel of FIG. 4.

FIG. 7 is a diagram illustrating a third configuration example of an image sensing device.

FIG. 8 is a diagram illustrating a fourth configuration example of an image sensing device.

FIG. 9 is a diagram illustrating an example of a Fresnel structure according to a color of light to be collected.

FIG. 10 is a diagram illustrating a fifth configuration example of an image sensing device.

FIG. 11 is a diagram illustrating a structure of a pixel of the image sensing device of FIG. 10.

FIG. 12 is a diagram illustrating a modification example of the pixel of FIG. 11.

FIG. 13 depicts diagrams illustrating a planar layout example of a light collection structure formed in linear shapes.

FIG. 14 depicts diagrams illustrating a planar layout example of a light collection structure formed in square shapes.

FIG. 15 depicts diagrams illustrating a planar layout example of a light collection structure formed in circular shapes.

FIG. 16 is a diagram illustrating a planar layout example of a structure obtained by applying pupil correction to the light collection structure formed in circular shapes.

FIG. 17 is a diagram that describes pupil correction of a light collection structure.

FIG. 18 is a diagram illustrating a planar layout example of a light collection structure to which pupil correction is applied.

FIG. 19 is a diagram that describes pupil correction of a light collection structure and a reflected light collection structure.

FIG. 20 is a diagram that describes a first production method for a pixel.

FIG. 21 is a diagram that describes the first production method for the pixel.

FIG. 22 is a diagram that describes the first production method for the pixel.

FIG. 23 is a diagram that describes a second production method for a pixel.

FIG. 24 is a block diagram illustrating a configuration example of an image sensing apparatus.

FIG. 25 is a diagram illustrating usage examples in which an image sensor is used.

### DESCRIPTION OF EMBODIMENTS

Hereinafter, specific embodiments to which the present technology is applied will be described in detail referring to the drawings.

### First Configuration Example of Pixel

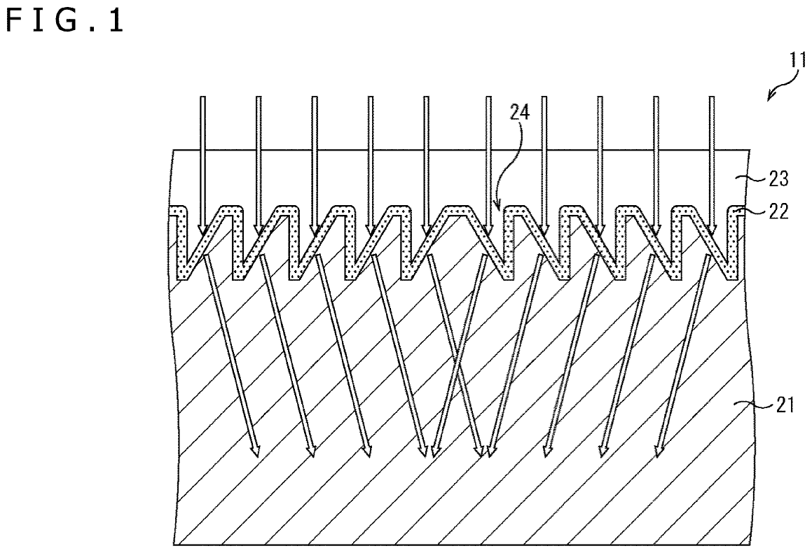

FIG. 1 is a diagram illustrating a configuration example of a first embodiment of a pixel to which the present technology is applied.

As illustrated in FIG. 1, a pixel 11 includes a semiconductor substrate 21, an antireflection film 22, and a protective film 23 that are laminated, and a light collection structure 24 is formed on the surface of the semiconductor substrate 21.

In the semiconductor substrate 21, there are formed photoelectric conversion sections (not illustrated) for receiving light applied to the pixel 11 and performing photoelectric conversion of the received light.

The antireflection film 22 is formed on the surface of the semiconductor substrate 21 to prevent the reflection of light applied to the semiconductor substrate 21. For example, the antireflection film 22 is formed such that a laminated structure in which a fixed charge film and an oxide film are laminated is disposed along the shape of the light collection structure 24. Further, as the antireflection film 22, for example, a thin insulating film that has a high dielectric constant (High-k) and that is produced by means of an ALD (Atomic Layer Deposition) method can be used. Specifically, as the antireflection film 22, hafnium oxide (HfO2), aluminum oxide (Al2O3), titanium oxide (TiO2), STO (Strontium Titan Oxide), or the like can be used. Further, it is preferred that, as the antireflection film 22, a laminated structure of, for example, a hafnium oxide film, an aluminum oxide film, and an oxide silicon film be used.

The protective film 23 is formed on the antireflection film 22 to protect the light collection structure 24. For example, the protective film 23 is formed such that the surface of the light collection structure 24 is flattened by a transparent inorganic material or a transparent organic material that is embedded into recessed portions of the light collection structure 24.

The light collection structure 24 collects, toward the center of the pixel 11, light incident on the semiconductor substrate 21, by allowing the surface shape of the semiconductor substrate 21 to have recessed-projected shapes that are formed symmetric with respect to the center of the pixel 11 and that include plural inclinations, an inclination of interest among which is inclined such that the further outside from the center of the pixel 11 the location of the inclination of interest is, the larger the depth of recessed portions corresponding to the inclination of interest is. That is, in the recessed-projected shapes of the light collection structure 24, plural recessed portions each including an inclined face and a vertical face are formed such that the light is collected toward the center of the pixel 11. Hereinafter, recessed-projected shapes having the function of collecting light, such as those of the light collection structure 24, will also be referred to as Fresnel shapes.

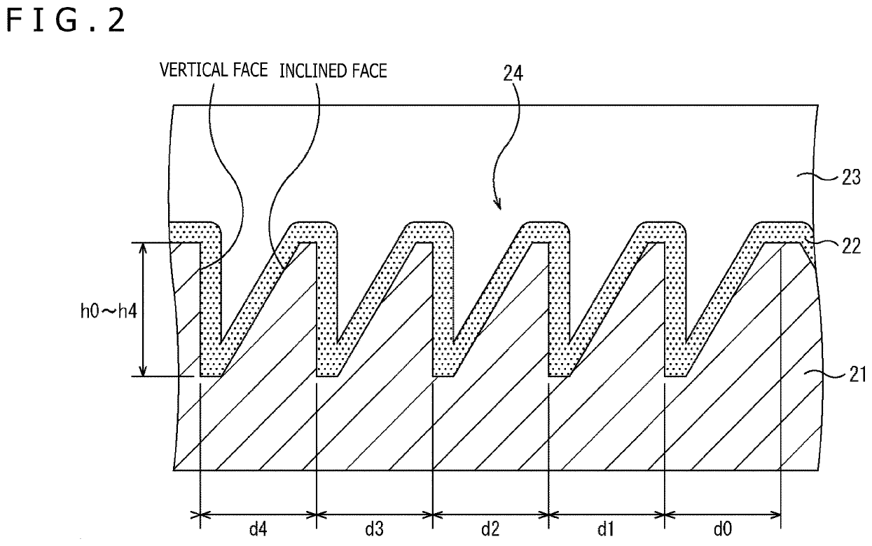

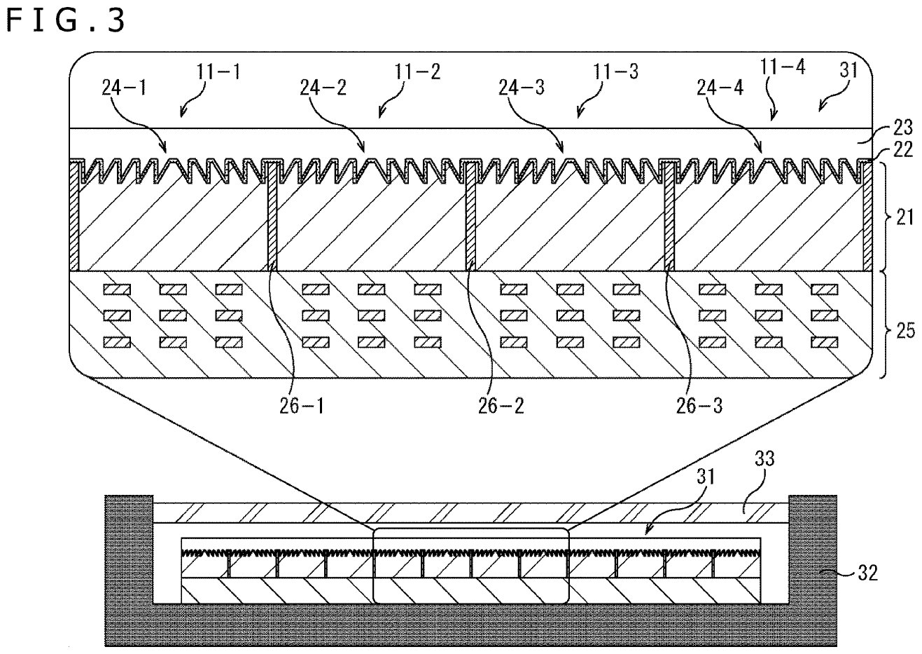

That is, as illustrated in FIG. 2, in cross-sectional view, the light collection structure 24 includes plural grooves each including a vertical face (first groove side face) disposed along a vertical direction relative to a face constituting the semiconductor substrate 21 and facing opposite to the light receiving face of the semiconductor substrate 21 (the face being a face on which a wiring layer 25 of FIG. 3 is formed) and an inclined face (second groove side face) disposed along a direction different from the vertical direction. Here, the vertical direction relative to the face constituting the semiconductor substrate 21 and facing opposite to the light receiving face of the semiconductor substrate 21 is a direction along the illustrated vertical face.

For example, in the pixel 11, in cross-sectional view, the plural grooves constituting the light collection structure 24 each include the vertical face and the inclined face such that the grooves are formed line-symmetric with respect to a vertical direction having a reference point on the center portion of the pixel 11. Further, in the pixel 11, in cross-sectional view, each of the grooves constituting the light collection structure 24 includes the vertical face and the inclined face such that the vertical face and the inclined face are formed asymmetric with respect to a vertical direction having a reference point on the bottom portion of the each of the grooves. Further, in cross-sectional view, the length of the vertical face is different from the length of the inclined face.

Moreover, the light collection structure 24 is formed such that the heights of the Fresnel shapes are uniform and that the widths of the Fresnel shapes are equal to one another or are formed such that the further outside the location of a Fresnel shape of interest among the Fresnel shapes is, the smaller the width of the Fresnel shape of interest is.

That is, as illustrated in FIG. 2, the light collection structure 24 is formed such that heights h from the recessed portions to the projected portions of the Fresnel shapes are uniform within the range of production error. For example, the light collection structure 24 is formed such that, in a configuration including five recessed-projected shapes, all heights h0 to h4 of the Fresnel shapes are uniform. For example, the light collection structure 24 is formed such that, in a configuration including n recessed-projected shapes, heights h0 to hn of the Fresnel shapes have relations represented by h0=h1=h2=h3=h4= . . . =hn.

Further, as illustrated in FIG. 2, the light collection structure 24 is formed such that widths d from the recessed portions to the projected portions of the Fresnel shapes are equal within the range of production error. For example, the light collection structure 24 is formed such that, in the configuration including five recessed-projected shapes, all widths d0 to d4 of the Fresnel shapes are equal. That is, the light collection structure 24 is formed such that, in the configuration including n recessed-projected shapes, widths d0 to dn of the Fresnel shapes have relations represented by d0=d1 =d2=d3=d4= . . . =dn.

Forming the light collection structure 24 in such a way as described above enables light incident on the semiconductor substrate 21 to be collected toward the center of the pixel 11. Thus, as illustrated by white arrows of FIG. 1, the light incident on the semiconductor substrate 21 can be refracted toward the center of the pixel 11 so as to be collected toward the center of the pixel 11.

Note that the light collection structure 24 may be formed such that the heights h of the Fresnel shapes are uniform and that the widths d of the Fresnel shapes are formed such that the further outside from the center of the pixel 11 the location of a Fresnel shape of interest among the Fresnel shapes is, the smaller the width d of the Fresnel shape of interest is (that is, such that relations represented by d0≥d1≥d2≥d3≥d4≥ . . . ≥dn are satisfied.) The light collection structure 24 configured in such a way as described above is capable of effectively collecting, toward the center of the pixel 11, the light incident on the semiconductor substrate 21, in such a way that the further outside the location of incident light of interest is, the larger the magnitude of the refraction of the incident light of interest toward the center of the pixel 11 is.

### First Configuration Example of Image Sensing Device

FIG. 3 illustrates a first configuration example of an image sensing device including plural pixels disposed therein.

As illustrated in FIG. 3, the image sensing device 31 is housed inside a package 32, and the opening portion of the package 32 is sealed by transparent glass 33.

The image sensing device 31 has a structure in which the wiring layer 25 including wiring for transmitting drive signals for driving the pixels 11, wiring for transmitting pixel signals output from the pixels 11, and other components is laminated on a face of the semiconductor substrate 21, the face being opposite to the light receiving face of the semiconductor substrate 21. Further, in the image sensing device 31 of the configuration example illustrated in FIG. 3, the surface of the protective film 23 is formed flat.

Moreover, the image sensing device 31 has a structure in which, in order to separate adjacent pixels 11, component separation portions 26 formed by embedding a material having a light-shielding property into trenches formed by engraving the semiconductor substrate 21 are disposed in the semiconductor substrate 21. For example, the component separation portions 26 include trenches having been formed from the side of the light receiving face on which the semiconductor substrate 21 receives light or trenches having been formed from the side of the face opposite the light receiving face (i.e., the face on which the wiring layer 25 is laminated.)

In each of the component separation portions 26, a dielectric material is embedded, or the dielectric material and a light-shielding film are embedded. This dielectric material can be made of a material such as a silicon oxide material, a hafnium oxide film, an aluminum oxide material, or a silicon nitride film.

Further, the light-shielding film can be made of, for example, a specific metallic material, a metal alloy material, a metal nitride material, or a material containing a metal silicide. Specifically, the light-shielding film is made of W (tungsten), Ti (titanium), Ta (tantalum), Ni (nickel), Mo (molybdenum), Cr (chromium), Ir (iridium), platinum iridium, TiN (titanium nitride), tungsten silicon compound, or the like. In addition, the component separation portions 26 may be formed by using a material other than the above materials, and can be formed by using, for example, a material having a light-shielding property other than metallic materials.

The image sensing device 31 has a structure in which the light collection structure 24 is disposed in each of the pixels 11, making it possible to produce the image sensing device 31 at a lower cost.

The image sensing device 31 configured in such a way as described above includes the light collection structures 24 on the light receiving face of the semiconductor substrate 21, allowing the light to be collected toward the center of each of the pixels 11 and making it possible to enhance the photoelectric conversion efficiency and achieve improvement of a property of receiving light for each of the pixels 11.

Further, the image sensing device 31 is capable of allowing the light collection structures 24 to prevent light rays applied to the pixels 11 from scattering to the left and right, enabling, for example, reduction of color mixing between adjacent pixels 11. Further, the structure of disposing the light collection structures 24 on the light receiving face of the semiconductor substrate 21 enables achievement of height reduction, sensitivity enhancement, and lower cost of the image sensing device 31.

### Second Configuration Example of Pixel

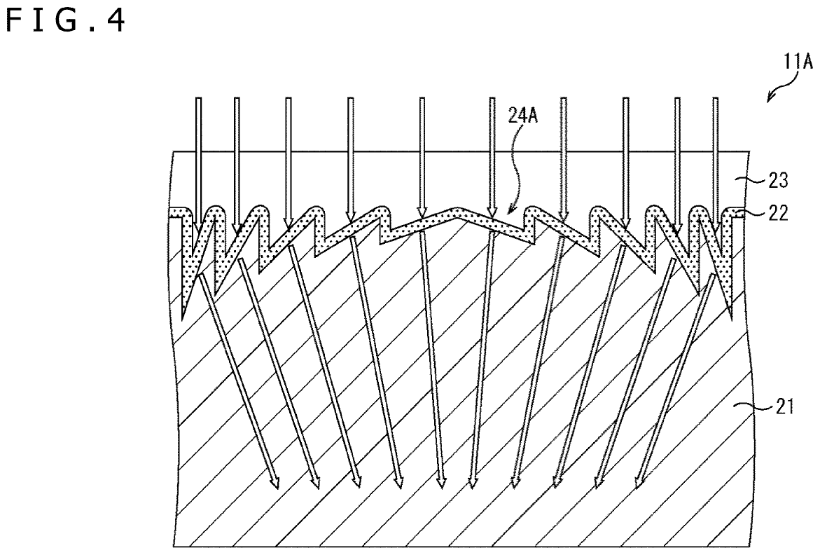

FIG. 4 is a diagram illustrating a configuration example of a second embodiment of the pixel to which the present technology is applied.

As illustrated in FIG. 4, a pixel 11A includes, as the pixel 11 of FIG. 1, the semiconductor substrate 21, the antireflection film 22, and the protective film 23 that are laminated. Further, in the pixel 11A, the shape of a light collection structure 24A is different from that of the light collection structure 24 of pixel 11 of FIG. 1.

That is, the light collection structure 24A is formed such that the further outside from the center of the pixel 11A the location of a Fresnel shape of interest among the Fresnel shapes is, the larger the height h from the recessed portion to the projected portion of the Fresnel shape of interest is.

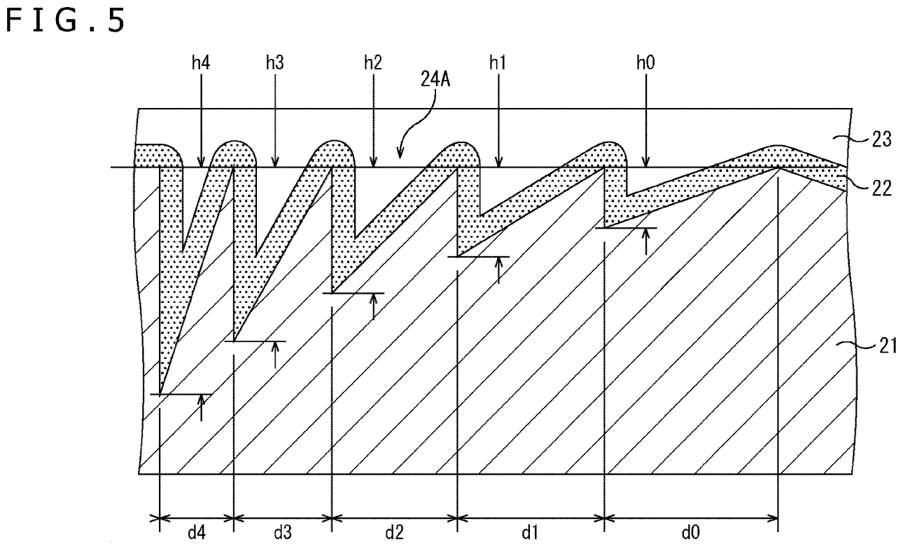

For example, as illustrated in FIG. 5, the light collection structure 24A is formed such that, in a configuration including five recessed-projected shapes, a height h0 of a first Fresnel shape from the center of the pixel 11A is the shortest and a height h1 of a second Fresnel shape from the center of the pixel 11A is larger than the height h0. Further, similar relations continue, and a height h4 of a fifth Fresnel shape from the center of the pixel 11A becomes the largest. That is, the light collection structure 24A is formed such that, in a configuration including n recessed-projected shapes, heights h0 to hn of the Fresnel shapes satisfy relations represented by h0≤h1≤h2≤h3≤h4≤ . . . ≤hn.

Further, as illustrated in FIG. 5, the light collection structure 24A is formed such that, as the location of a Fresnel shape of interest among the Fresnel shapes is shifted outside from the center of the pixel 11A, the width d from the recessed portion to the projected portion of the Fresnel shape of interest becomes equal to or smaller than the width d of the immediately anterior Fresnel shape of interest. For example, the light collection structure 24A is formed such that, in a configuration including five recessed-projected shapes, a width d0 of a first Fresnel shape from the center of the pixel 11A is the largest and a width dl of a second Fresnel shape from the center of the pixel 11A is smaller than the width d0. Further, similar relations continue, and a width d4 of a fifth Fresnel shape from the center of the pixel 11A becomes the smallest. That is, the light collection structure 24A is formed such that, in the configuration including n recessed-projected shapes, widths d0 to hn of the Fresnel shapes satisfy relations represented by d0≥d1≥d2≥d3 ≥d4≥ . . . ≥dn.

Forming the light collection structure 24A in such a way as described above makes it possible to allow the refraction of light to be controlled in such a manner that the refraction of light in the vicinity of the center of the pixel 11A is small and that the further outside from the center of the pixel 11A the location of light of interest is, the larger the magnitude of the refraction of the light of interest is. Thus, as illustrated by white arrows of FIG. 4, the light incident on the semiconductor substrate 21 can be effectively collected toward the center of the pixel 11A in such a way that the further outside the location of incident light of interest is, the larger the magnitude of the refraction of the incident light of interest toward the center of the pixel 11A is.

In addition, the light collection structure 24A may be formed in such a manner that the further outside from the center of the pixel 11A the location of a Fresnel shape of interest is, the larger the height h of the Fresnel shape of interest is, and that the widths d of the Fresnel shapes are equal (that is, d0=d1=d2=d3=d4= . . . =dn) within the range of production error. The light collection structure 24A configured in such a way as described above also makes it possible to collect, toward the center of the pixel 11A, the light incident on the semiconductor substrate 21, and enhance the sensitivity of the pixel 11A.

### Second Configuration Example of Image Sensing Device

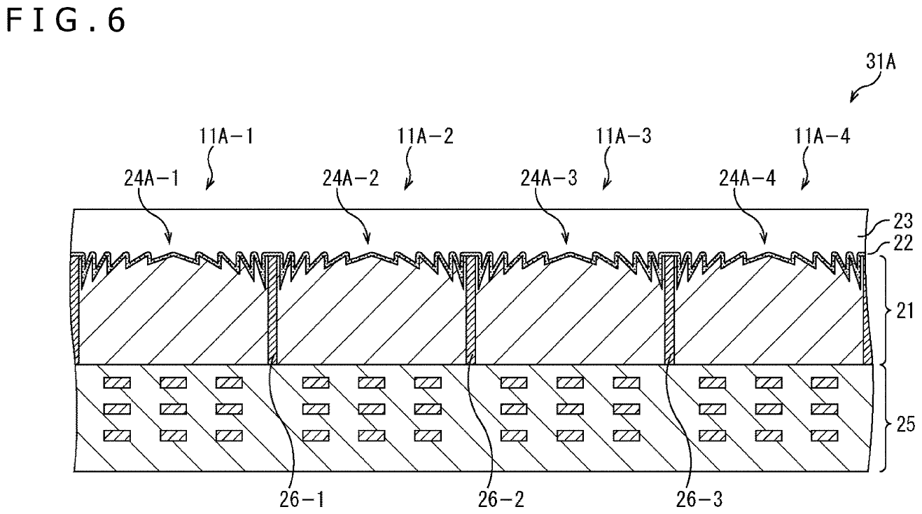

FIG. 6 illustrates a second configuration example of an image sensing device including plural pixels disposed therein.

As illustrated in FIG. 6, in an image sensing device 31A, similarly to the image sensing device 31 of FIG. 3, the wiring layer 25 is laminated on the semiconductor substrate 21, and the surface of the protective film 23 is formed flat. Further, in the image sensing device 31A as well, the component separation portions 26 each for separating corresponding adjacent ones of pixels 11A are formed in the semiconductor substrate 21.

Further, in the image sensing device 31A, the light collection structure 24A having been described above with reference to FIGS. 4 and 5 is formed, for each of the pixels 11A, on the surface of the semiconductor substrate 21.

In addition, although not illustrated, similarly to the image sensing device 31 of FIG. 3, the image sensing device 31A is also housed inside the package 32, and the opening portion of the package 32 is sealed by the transparent glass 33.

The image sensing device 31A configured in such a way as described above makes it possible, as the image sensing device 31 of FIG. 3, to achieve improvement of a property of receiving light for each of the pixels 11A.

### Third Configuration Example of Image Sensing Device

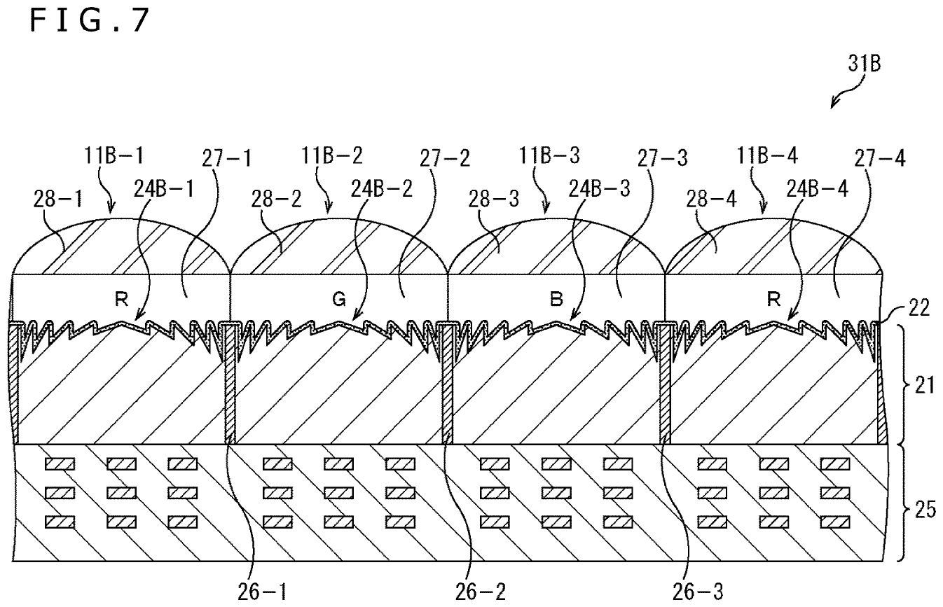

FIG. 7 illustrates a third configuration example of an image sensing device including plural pixels disposed therein.

As illustrated in FIG. 7, in an image sensing device 31B, similarly to the image sensing device 31 of FIG. 3, the wiring layer 25 is laminated on the semiconductor substrate 21, and the component separation portions 26 each for separating corresponding adjacent ones of pixels 11B are formed in the semiconductor substrate 21. Further, in the image sensing device 31B, for each of the pixels 11B, a corresponding light collection structure 24B having a shape similar to that of the light collection structure 24A of the image sensing device 31A of FIG. 6 is formed on the surface of the semiconductor substrate 21.

Further, the image sensing device 31B is configured such that color filters 27 and on-chip lenses 28 are laminated on the side of the light receiving face of the semiconductor substrate 21 via the antireflection film 22.

For each of the pixels 11B, a corresponding one of the color filters 27 transmits light having a color of light to be received by a corresponding one of the pixels 11B. For example, in the configuration example of FIG. 7, a color filter 27-1 transmits red (R) light, a color filter 27-2 transmits green (G) light, a color filter 27-3 transmits blue (B) light, and a color filter 27-4 transmits red (R) light. Note that, in addition to such a configuration, for example, a configuration using a filter that transmits near-infrared light, a transparent filter, and/or a color filter that transmits different color light may be employed.

For each of the pixels 11B, a corresponding one of the on-chip lenses 28 collects light to be received by each of the pixels 11B.

In addition, although not illustrated, similarly to the image sensing device 31 of FIG. 3, the image sensing device 31B is also housed inside the package 32, and the opening portion of the package 32 is sealed by the transparent glass 33.

The image sensing device 31B configured in such a way as described above makes it possible, as the image sensing device 31 of FIG. 3, to achieve improvement of a property of receiving light for each of the pixels 11B. Moreover, unlike the solid-state image sensing device disclosed in PTL 1 described above, the image sensing device 31B is capable of capturing a color image containing not only monochromatic light such as infra-red rays but also light of other wavelengths, by reducing the color mixing for light rays.

### Fourth Configuration Example of Image Sensing Device

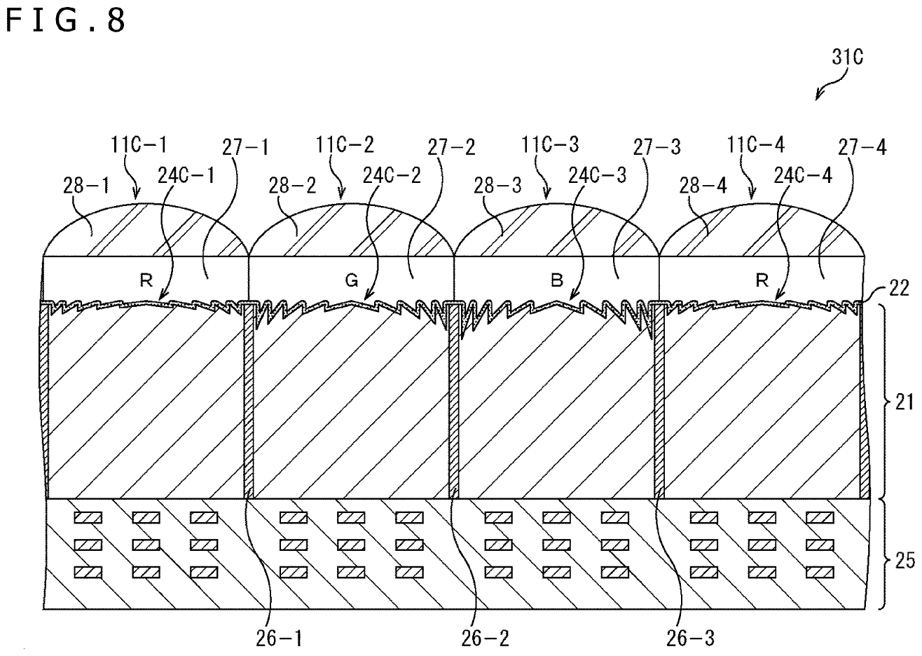

FIG. 8 illustrates a fourth configuration example of an image sensing device including plural pixels disposed therein.

As illustrated in FIG. 8, similarly to the image sensing device 31B of FIG. 7, an image sensing device 31C is configured such that the wiring layer 25 is laminated on the semiconductor substrate 21 and that the color filters 27 and the on-chip lenses 28 are laminated on the side of the light receiving face of the semiconductor substrate 21 via the antireflection film 22. Further, in the image sensing device 31C as well, the component separation portions 26 each for separating corresponding adjacent ones of pixels 11C are formed in the semiconductor substrate 21.

Further, the image sensing device 31C is configured in such a manner that, for each of the pixels 11C, the shape of a corresponding one of light collection structures 24C differs according to the color (the wavelength) of light transmitted by a corresponding one of the color filters 27.

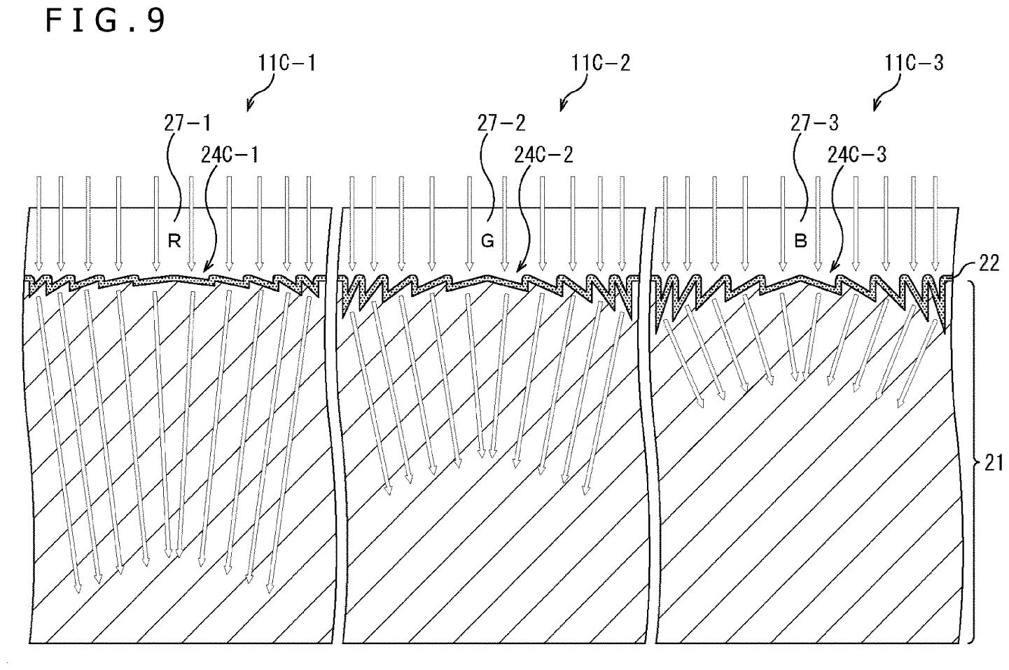

For example, as illustrated in FIG. 9, in a pixel 11C-1 in which a color filter 27-1 that transmits red light of a long wavelength is disposed, in order to cause the light to be collected in a deeper region of the semiconductor substrate 21, a light collection structure 24C-1 is formed in a shape including Fresnel shapes having shallow recessed portions and gentle angle inclinations.

Further, in a pixel 11C-3 in which a color filter 27-3 that transmits blue light of a short wavelength is disposed, in order to cause the light to be collected in a shallow region of the semiconductor substrate 21, a light collection structure 24C-3 is formed in a shape including Fresnel shapes having deep con recessed cave portions and steep angle inclinations.

Further, in a pixel 11C-2 in which a color filter 27-2 that transmits green light of a wavelength shorter than that of the red light but longer than that of the blue light is disposed, in order to cause the light to be collected in an intermediate region between the regions for the light collection structures 24C-1 and 24C-3, a light collection structure 24C-2 is formed in a shape including Fresnel shapes having recessed portions and inclinations, the depths of the recessed portions and the angles of the inclinations being intermediate depths and angles between those for the light collection structures 24C-1 and those for the light collection structures 24C-3.

The image sensing device 31C configured in such a way as described above makes it possible, as the image sensing device 31 of FIG. 3, to achieve improvement of a property of receiving light for each of the pixels 11C. Further, the image sensing device 31C is capable of optimizing, for each of colors of light rays to be received by the pixels 11C, the collection of a corresponding one of the light rays.

In addition, for example, in a configuration in which a filter that transmits the near-infrared light is used instead of the color filter 27, as one of kinds of the light collection structures 24, the light collection structure 24C is formed in a shape that allows the light to reach a further deeper region of the semiconductor substrate 21 than the region for the pixel 11C-1 in which the color filter 27-1 is disposed.

### Fifth Configuration Example of Image Sensing Device

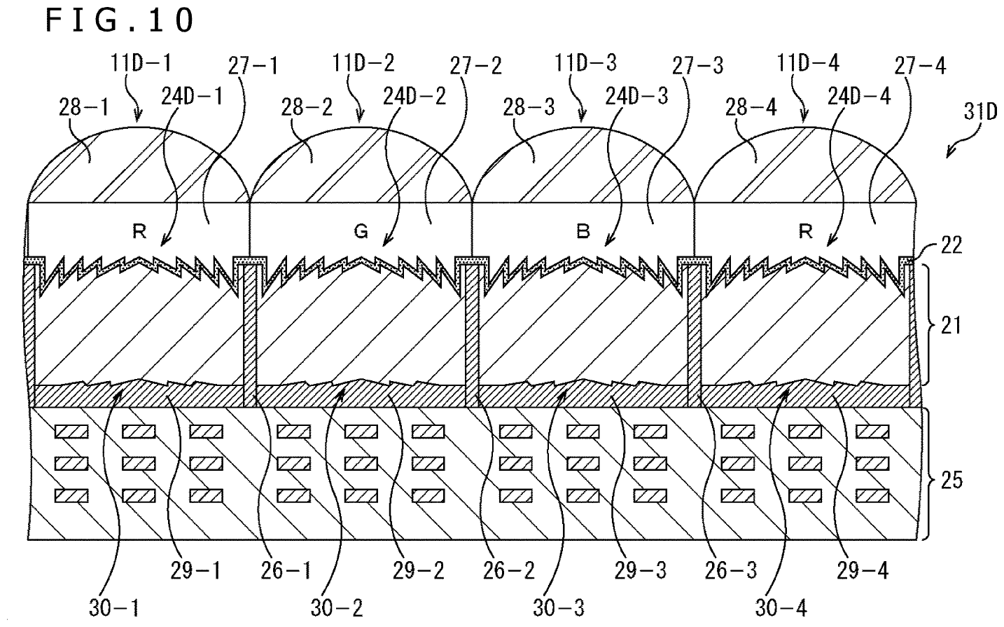

FIG. 10 illustrates a fifth configuration example of an image sensing device including plural pixels disposed therein.

As illustrated in FIG. 10, similarly to the image sensing device 31B of FIG. 7, an image sensing device 31D is configured in such a manner that the wiring layer 25 is laminated on the semiconductor substrate 21 and that the color filters 27 and the on-chip lenses 28 are laminated on the side of the light receiving face of the semiconductor substrate 21 via the antireflection film 22. Further, in the image sensing device 31D, the component separation portions 26 each for separating corresponding adjacent ones of pixels 11D are formed in the semiconductor substrate 21, and light collection structures 24D having shapes similar to those of the light collection structures 24A of the image sensing device 31A of FIG. 6 are formed on the surface of the semiconductor substrate 21.

Further, the image sensing device 31D is configured such that, for each of the pixels 11D, a corresponding one of reflective films 29 is disposed between the semiconductor substrate 21 and the wiring layer 25, and a corresponding one of reflected light collection structures 30 is formed on the corresponding one of the reflective films 29.

The reflective films 29 are configured by a metallic material formed on a face of the semiconductor substrate 21, the face being opposite to the light receiving face of the semiconductor substrate 21, and reflect light having been transmitted through the semiconductor substrate 21.

Each of the reflected light collection structures 30 is formed in a Fresnel shape that directs light reflected at a corresponding one of the reflective films 29 toward the center of a corresponding one of the pixels 11D.

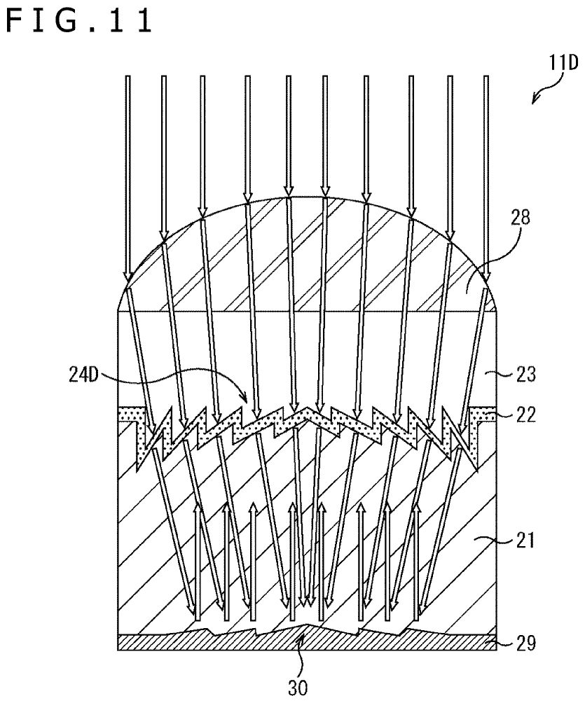

For example, as illustrated in FIG. 11, a reflected light collection structure 30 of a reflective film 29 reflects light having been transmitted through the semiconductor substrate 21 toward the center of a pixel 11D.

The image sensing device 31D configured in such a way as described above makes it possible, as the image sensing device 31 of FIG. 3, to achieve improvement of a property of receiving light for each of the pixels 11D. Moreover, the image sensing device 31D makes it possible to achieve further enhancement of the sensitivity by means of the reflective films 29 including the reflected light collection structures 30.

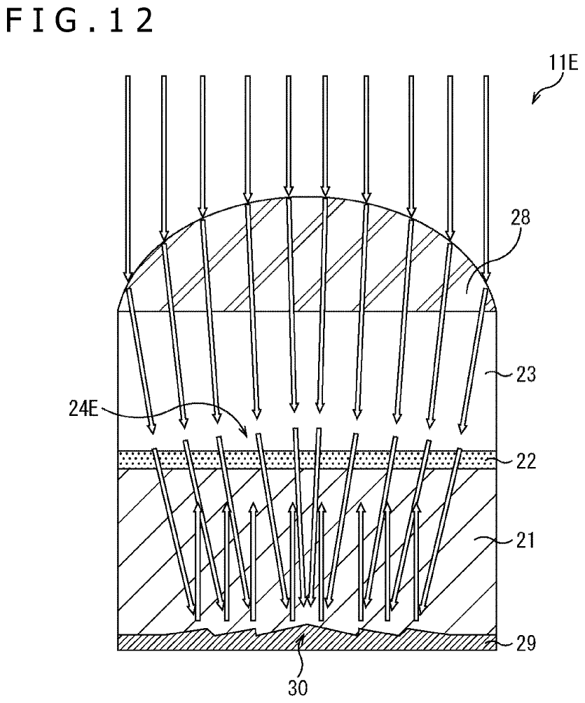

Note that, in the above configuration in which the reflective films 29 including the reflected light collection structures 30 are disposed and the collection of light is made by the reflective films 29, a modification example in which, as a pixel 11E of FIG. 12, a light collection structure 24E disposed on the light receiving face of the semiconductor substrate 21 is formed flat may be employed.

### Planar Layout Examples of Fresnel Structures

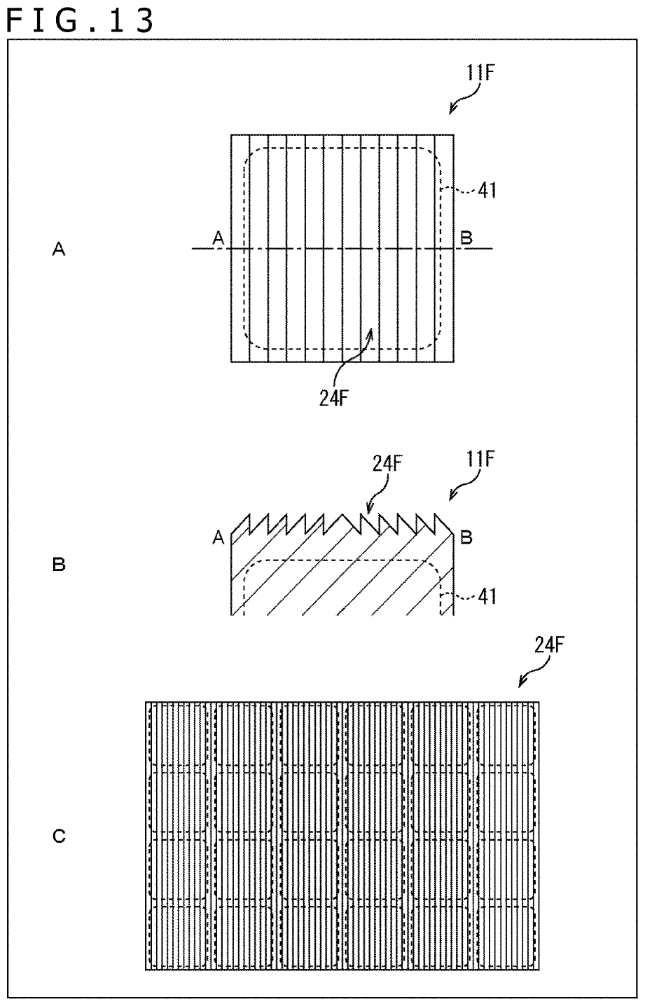

Planar layouts of the light collection structure 24 will be described with reference to FIGS. 13 to 16.

FIG. 13 illustrates a planar layout example of a light collection structure 24F formed in elongated linear shapes in plan view.

In FIG. 13, A illustrates a planar configuration of a pixel 11F in which the light collection structure 24F is disposed, and B illustrates a cross-sectional configuration of the pixel 11F in which the light collection structure 24F is disposed (that is, B of FIG. 13 illustrates a cross-sectional view of the pixel 11F, taken along an alternate long and short dash line A-B illustrated in A of FIG. 13.) The light collection structure 24F includes inclined faces similar to those of the light collection structure 24 of FIG. 1, and has a shape in which the inclined faces are inclined toward both sides of the pixel 11F so as to be formed line-symmetric.

Further, in FIG. 13, each of photoelectric conversion sections 41 formed in the semiconductor substrate 21 is illustrated in a dashed line, and in C of FIG. 13, the dashed lines of the photoelectric conversion sections 41 represent a state in which plural pixels 11F are arranged in rows and columns. As illustrated, the light collection structures 24F are formed so as to be arranged along a column direction over the plurality of pixels 11F. Such a light collection structure 24F is suitable for application to, for example, a line-type sensor.

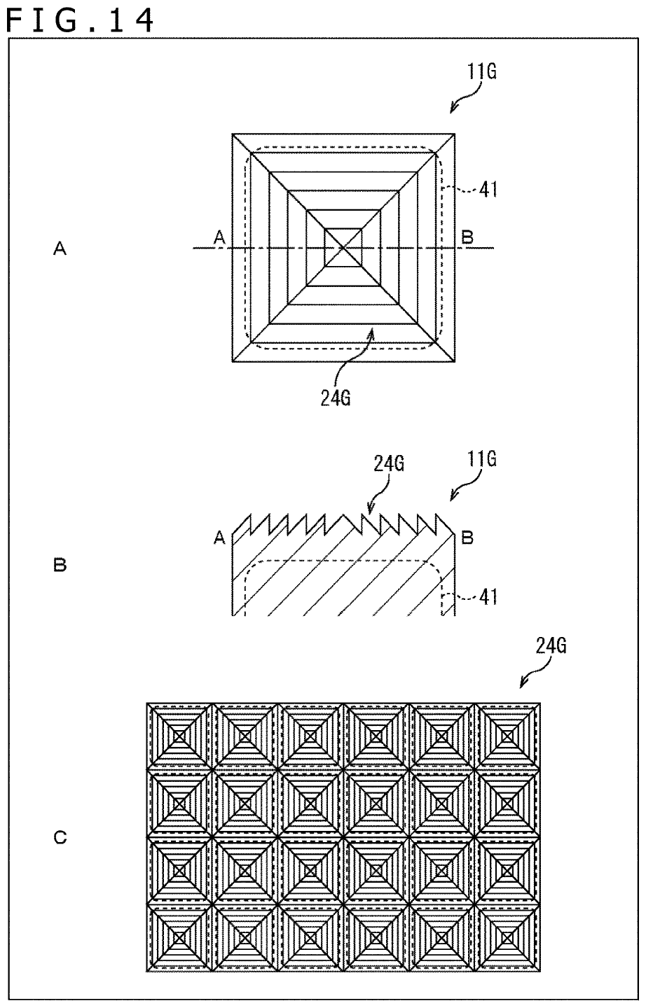

FIG. 14 illustrates a planar layout example of a light collection structure 24G formed in square shapes in plan view

In FIG. 14, A illustrates a planar configuration of a pixel 11G in which the light collection structure 24G is disposed, and B illustrates a cross-sectional configuration of the pixel 11G in which the light collection structure 24G is disposed (that is, B of FIG. 14 illustrates a cross-sectional view of the pixel 11G, taken along an alternate long and short dash line A-B illustrated in A of FIG. 14.) The light collection structure 24G includes inclined faces similar to those of the light collection structure 24 of FIG. 1, and has a shape in which the inclined faces are inclined toward the four edges of the pixel 11G so as to be formed point-symmetric with respect to the center of the pixel 11G.

Further, in FIG. 14, each of the photoelectric conversion sections 41 formed in the semiconductor substrate 21 is illustrated in a dashed line, and in C of FIG. 14, the dashed lines of the photoelectric conversion sections 41 represent a state in which plural pixels 11G are arranged in rows and columns. As illustrated, the light collection structures 24G are formed such that the square shapes formed for each of the plural pixels 11G are repeated in the row direction and the column direction.

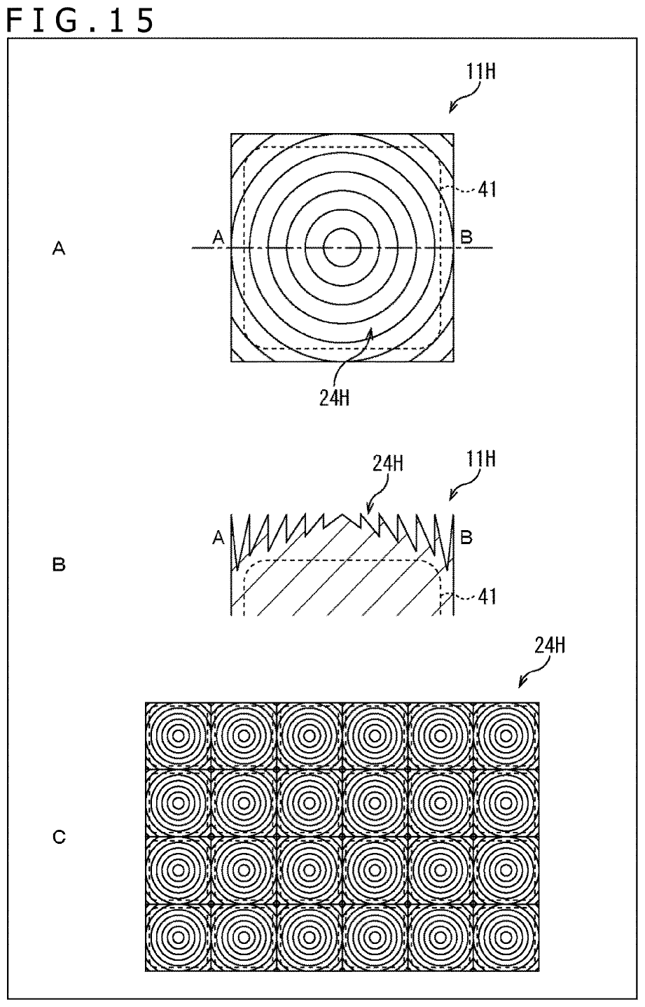

FIG. 15 illustrates a planar layout example of a light collection structure 24H formed in circular shapes in plan view.

In FIG. 15, A illustrates a planar configuration of a pixel 11H in which the light collection structure 24H is disposed, and B illustrates a cross-sectional configuration of the pixel 11H in which the light collection structure 24H is disposed (that is, B of FIG. 15 illustrates a cross-sectional view of the pixel 11H, taken along an alternate long and short dash line A-B illustrated in A of FIG. 15.) The light collection structure 24H includes inclined faces similar to those of the light collection structure 24A of FIG. 4, and has a shape in which the inclined faces are inclined toward the periphery of the pixel 11H so as to form concentric circles relative to the center of the pixel 11H (the shape being what is called a Fresnel lens shape.)

Further, in FIG. 15, each of the photoelectric conversion sections 41 formed in the semiconductor substrate 21 is illustrated in a dashed line, and in C of FIG. 15, the dashed lines of the photoelectric conversion sections 41 represent a state in which plural pixels 11H are arranged in rows and columns. As illustrated, the light collection structures 24H are formed such that the circular shapes formed for each of the plural pixels 11G are repeated in the row direction and the column direction.

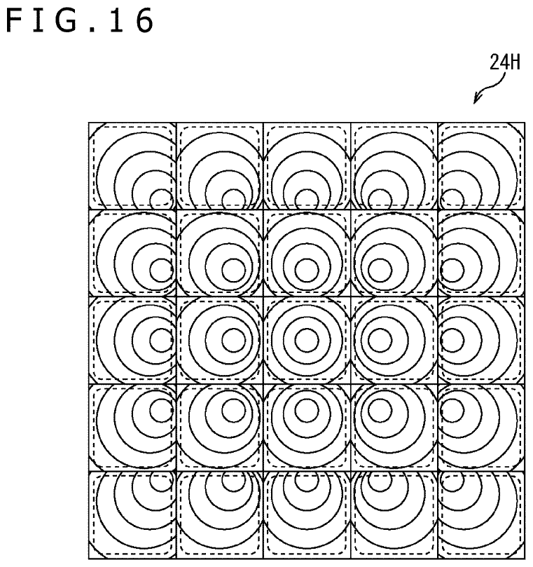

FIG. 16 illustrates a planar layout example of a configuration in which pupil correction is applied to the light collection structures 24H each formed in the circular shapes in plan view.

In FIG. 16, similarly to C of FIG. 15, the dashed lines of the photoelectric conversion sections 41 represent a state in which the plural pixels 11H are arranged in rows and columns. As illustrated in FIG. 16, in the light collection structures 24H to which the pupil correction is applied, a pixel 11H disposed at the center of the whole has a shape in which the center of a corresponding light collection structure 24H is placed at the center of the pixel 11H, and a pixel 11H of interest other than the above pixel 11H is shaped such that the further outside the location of the pixel 11H of interest is, the closer to the center portion of the whole the location of the center of a corresponding light collection structure 24H is. Such light collection structures 24H to which the pupil correction is applied are suitable for application to, for example, a sensor for a point light source.

Note that the planar shape of the light collection structure 24 is not limited to those of the configuration examples illustrated in FIGS. 13 to 16, and other various shapes can be employed.

### Pupil Correction for Light Collection Structure

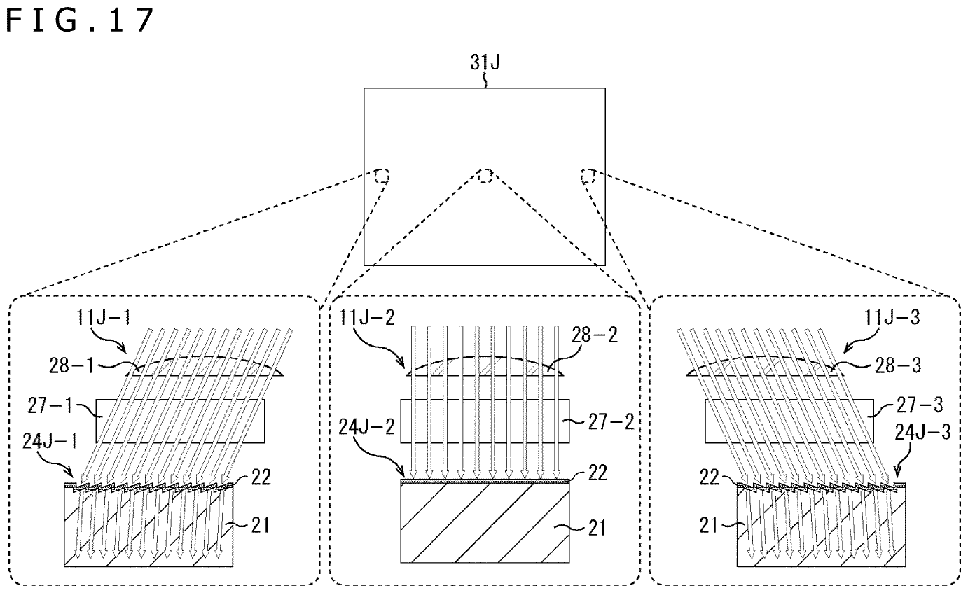

The pupil correction for the light collection structures 24 will be described with reference to FIGS. 17 to 19.

FIG. 17 illustrates schematic cross-sectional configurations of a pixel 11J-1 disposed near the left edge of an image sensing device 31J, a pixel 11J-2 disposed at the center portion of the image sensing device 31J, and a pixel 11J-3 disposed near the right edge of the image sensing device 31J.

As illustrated, in the pixel 11J-2 disposed at the center portion of the image sensing device 31J, a light collection structure 24J-2 is formed on the light receiving face of the semiconductor substrate 21. Further, a light collection structure 24J-1 of the pixel 11J-1 and a light collection structure 24J-3 of the image sensing device 31J-3 are formed such that the closer to outside portions where the image height of the image sensing device 31J is high the locations of the light collection structures 24J-1 and 24J-3 are, the larger the depths of the recessed portions of the Fresnel shapes of each of the light collection structures 24J-1 and 24J-3 are.

Further, the pupil correction is made such that the locations of the on-chip lenses 28 and those of the color filters 27 are shifted relative to a point light source and that each of the light collection structures 24J formed on the surface of the semiconductor substrate 21 is formed in such a way as to cause, according to the location of each of the light collection structures 24J, the light to be collected toward the center of a corresponding one of the pixels 11J.

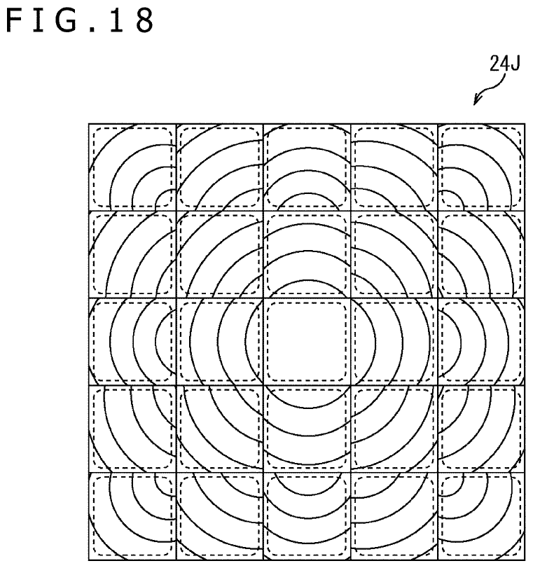

FIG. 18 illustrates a planar layout example of the light collection structures 24J formed in such a way as described above. As illustrated in FIG. 18, the light collection structures 24J are each formed in fan shapes widened toward the outside from the center portion of the whole in plan view.

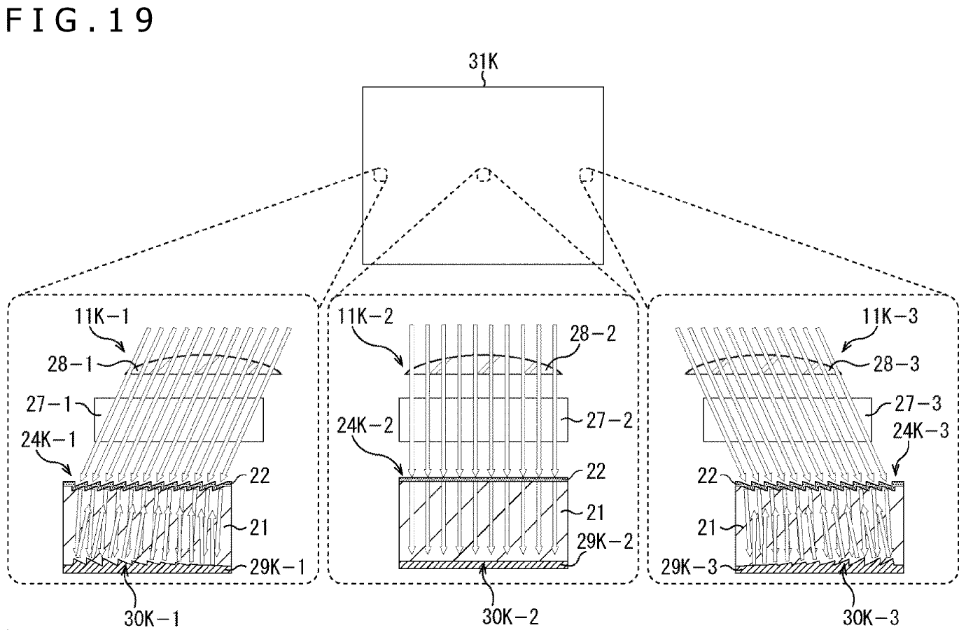

A configuration example of an image sensing device 31K obtained by applying the pupil correction to pixels 11K including the reflective films 29 having the reflected light collection structures 30, which has been described with reference to FIG. 10, will be described with reference to FIG. 19.

FIG. 19 illustrates schematic cross-sectional configurations of a pixel 11K-1 disposed near the left edge of the image sensing device 31K, a pixel 11K-2 disposed at the center portion of the image sensing device 31K, and a pixel 11K-3 disposed near the right edge of the image sensing device 31K.

As illustrated, in the pixel 11K-2 disposed at the center portion of the image sensing device 31K, a light collection structure 24K-2 is formed flat on the light receiving face of the semiconductor substrate 21 and a reflected light collection structure 30K of a corresponding reflective film 29K is formed flat. Further, a light collection structure 24K-1 of the pixel 11K-1 and a light collection structure 24K-3 of the image sensing device 31K-3 are formed such that the closer to outside portions where the image height of the image sensing device 31K is high the locations of the light collection structures 24K-1 and 24K-3 are, the larger the depths of recessed portions of the Fresnel shapes of each of the light collection structures 24K-1 and 24K-3 are and the larger the depths of recessed portions of the Fresnel shapes of each of reflected light collection structures 30K of corresponding reflective films 29K are. That is, the sizes of the reflective films 29K differ according to corresponding image heights, and each of the reflective films 29K is formed in such a way as to cause, according to the location of the each of the reflective films 29K, the light to be collected toward the center of a corresponding one of the pixels 11J.

### Production Method for Pixel

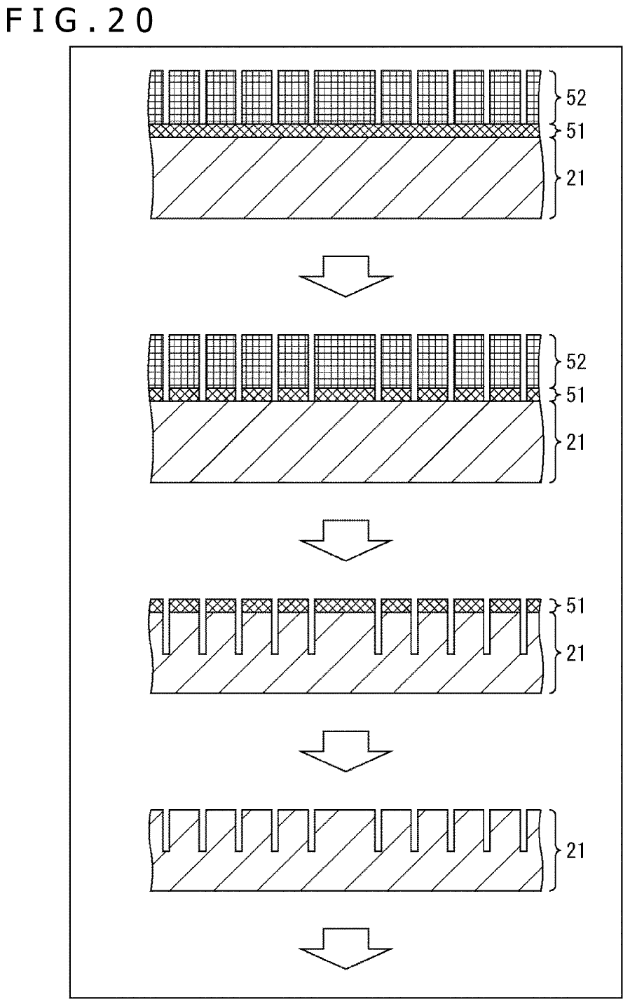

A production method for the pixel 11 of FIG. 1 will be described with reference to FIGS. 20 to 22.

In a first step, as illustrated in the first row from the top of FIG. 20, a SiN film 51 is formed onto the light receiving face of the semiconductor substrate 21, and masks are formed onto the SiN film 51 with a resist material 52.

In a second step, as illustrated in the second row from the top of FIG. 20, dry etching is performed on the SiN film 51 by using the resist material 52 as masks therefor.

In a third step, as illustrated in the third row from the top of FIG. 20, the resist material 52 is removed, and dry etching is performed on the semiconductor substrate 21 by using the SiN film 51 as masks therefor, to form the trenches.

In a fourth step, as illustrated in the fourth row from the top of FIG. 20, the SiN film 51 is removed.

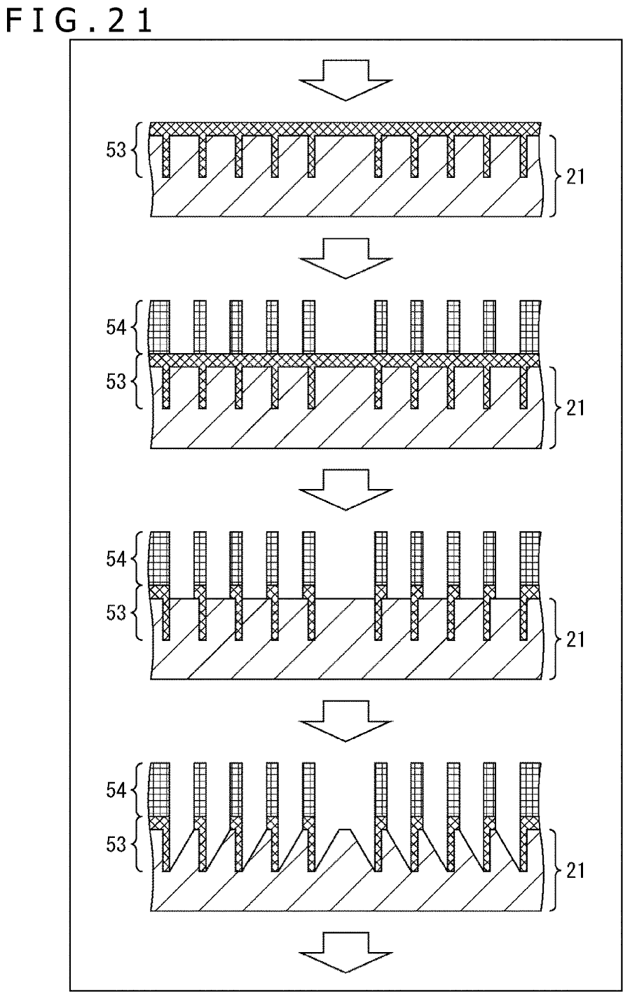

In a fifth step, as illustrated in the first row from the top of FIG. 21, a SiN film 53 is formed, and further, the trenches of the semiconductor substrate 21 are filed with the SiN film 53.

In a sixth step, as illustrated in the second row from the top of FIG. 21, masks are formed onto the SiN film 53 with a resist material 54.

In a seventh step, as illustrated in the third row from the top of FIG. 21, dry etching is performed on the SiN film 53 by using the resist material 54 as masks therefor.

In an eighth step, as illustrated in a fourth row from the top of FIG. 21, dry etching or wet etching is performed on the semiconductor substrate 21 by using the SiN film 53 as masks therefor. At this time, inclinations serving as the light collection structure 24 are formed by performing anisotropic etching (using an Si100 face.)

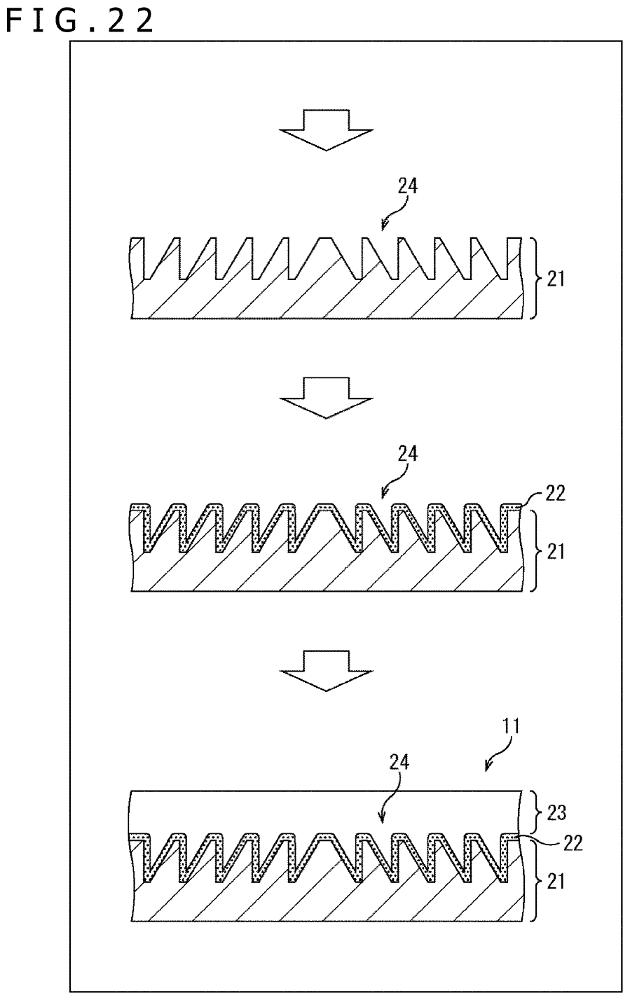

In a ninth step, as illustrated in the first row from the top of FIG. 22, the SiN film 53 and the resist material 54 are removed.

In a 10th step, as illustrated in the second row from the top of FIG. 22, the antireflection film 22 is formed by forming SIO onto the light collection structure 24. For example, as the antireflection film 22, as described above, the laminated structure of the hafnium oxide film, the aluminum oxide film, and the oxide silicon film can be used.

In an 11th step, as illustrated in the third row from the top of FIG. 22, the protective film 23 is formed, and thereby, the pixel 11 in which the light collection structure 24 is formed on the light receiving face of the semiconductor substrate 21 is produced.

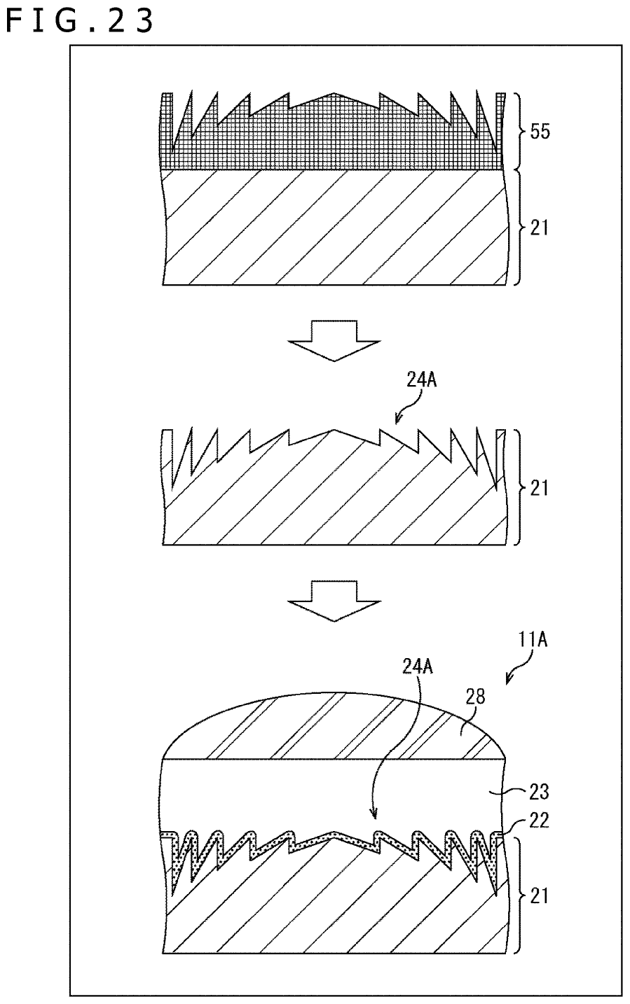

A production method for the pixel 11A of FIG. 4 will be described with reference to FIG. 23.

In a 21st step, as illustrated in the first row from the top of FIG. 23, as desired shapes, Fresnel shapes corresponding to the light collection structure 24A are formed in a mold for nanoimprint. Further, a resist material 55 having the Fresnel shapes is produced on the light receiving face of the semiconductor substrate 21 by means of the nanoimprint.

In a 22nd step, as illustrated in the second row from the top of FIG. 23, the Fresnel shapes of the resist material 55 are copied on the light receiving face of the semiconductor substrate 21 by performing a process using dry etching, and the light collection structure 24A is formed.

In a 23rd step, as illustrated in the third row from the top of FIG. 23, the color filter 27 and the on-chip lens 28 are formed subsequent to forming the antireflection film 22 on the light collection structure 24A, and thereby, the pixel 11A in which the light collection structure 24A is formed on the light receiving face of the semiconductor substrate 21 is produced.

### Configuration Example of Electronic Equipment

The image sensing device 31 described above can be applied to various kinds of electronic equipment, such as an image sensing system encompassing a digital still camera, a digital video camera, etc., a mobile phone having an image sensing function, and any other kind of equipment having an image sensing function.

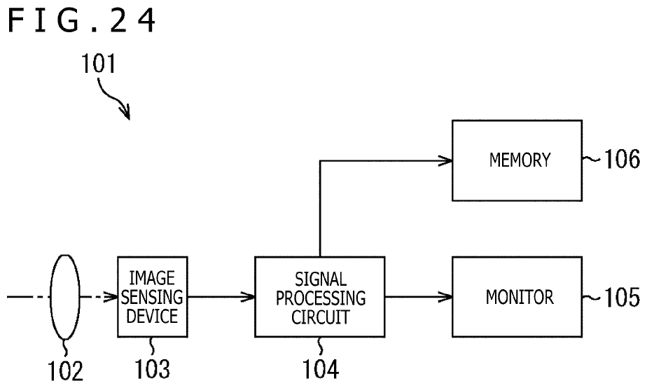

FIG. 24 is a block diagram illustrating a configuration example of an image sensing apparatus mounted in electronic equipment.

As illustrated in FIG. 24, an image sensing apparatus 101 includes an optical system 102, an image sensing device 103, a signal processing circuit 104, a monitor 105, and a memory 106, and is capable of capturing still images and moving images.

The optical system 102 includes one or plural lenses, and guides, to the image sensing device 103, image light (incident light) from an object, and allows the image light to be focused into an image on a light receiving face (sensor portion) of the image sensing device 103.

As the image sensing device 103, the image sensing device 31 described above is applied. Electrons according to the image into which the image light has been focused on the light receiving face through the optical system 102 are stored in the image sensing device 103 for a constant period of time. Further, a signal according to the electrons having been stored in the image sensing device 103 is supplied to the signal processing circuit 104.

The signal processing circuit 104 performs various kinds of signal processing on the pixel signal having been output from the image sensing device 103. An image (image data) having been obtained by the signal processing performed by the signal processing circuit 104 is supplied to and displayed on the monitor 105 and/or supplied to and stored (recorded) in the memory 106.

In the image sensing apparatus 101 configured in such a way as described above, the usage of the above-described image sensing device 31 enables, for example, capturing of images with higher sensitivity.

### Usage Examples of Image Sensor

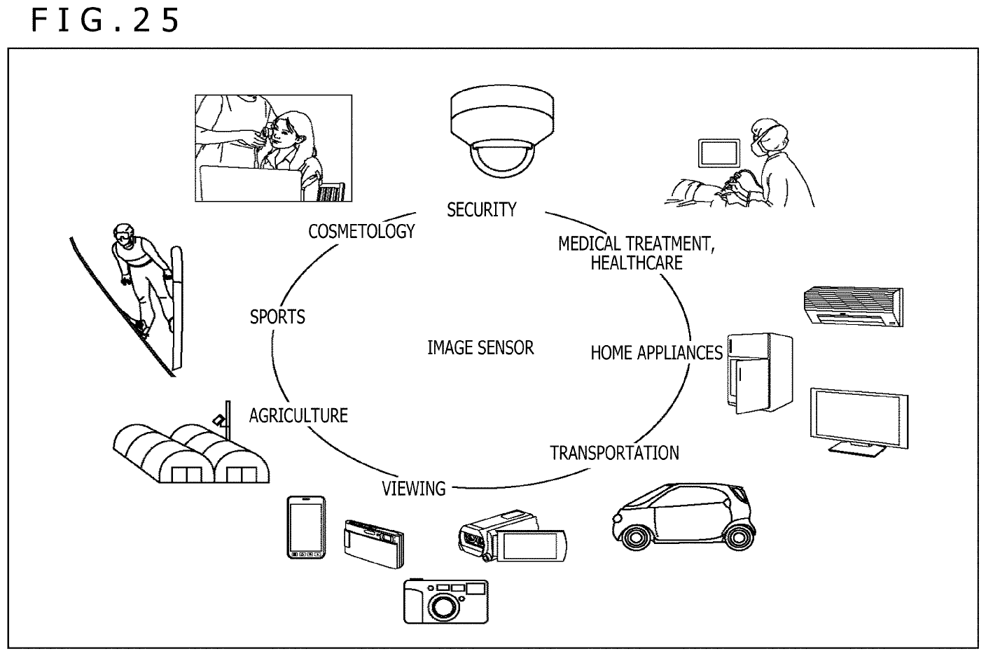

FIG. 25 is a diagram illustrating usage examples in which the above-described image sensor (image sensing device) is used.

The above-described image sensor can be used in various cases described below in which sensing of light, such as visible light, infrared light, ultraviolet light, and X-rays, is performed.
Apparatuses for capturing images for use in viewing, such as a digital camera and portable equipment having a camera function
Apparatuses used for transportation, such as an in-vehicle sensor for capturing the front, rear, surroundings, and interior of an automobile, for the purpose of safe driving including automatic stop and the like, recognition of driver's conditions, and any other kind of monitoring; a monitoring camera for monitoring traveling vehicles and roads; and a distance measurement sensor for measuring vehicle-to-vehicle distances, and any other distance
Apparatuses mounted in home appliances such as a TV, a refrigerator, and an air conditioner, for the purpose of capturing a user's gesture and performing an equipment operation according to the gesture
Apparatuses used for medical treatments and healthcare, such as an endoscope and an apparatus for performing angiography using received infrared light
Apparatuses used for security, such as a surveillance camera for use in crime prevention and a camera for use in person authentication
Apparatuses used for cosmetology, such as a skin measurement instrument for capturing skin and a microscope for capturing scalp
Apparatuses used for sports, such as an action camera and a wearable camera for use in sports
Apparatuses used for agriculture, such as a camera for monitoring the states of fields and crops

### Configuration Combination Examples

It should be noted that the present technology can also have the following configurations.

(1)

A sensor device including:

a semiconductor substrate including a first face on which light is incident and a second face facing opposite to the first face;

plural pixels each including a photoelectric conversion region used for performing photoelectric conversion and disposed in the semiconductor substrate; and

plural grooves disposed on the first face of each of the pixels,

in which, in cross-sectional view, the grooves each include a first groove side face disposed along a vertical direction relative to the second face of the semiconductor substrate and a second groove side face disposed in a direction different from the vertical direction.

(2)

The sensor device according to (1), in which, in cross-sectional view, the plural grooves disposed in each of the pixels each include the first groove side face and the second groove side face such that the grooves are formed line-symmetric with respect to the vertical direction having a reference point on a center portion of each of the pixels.

(3)

The sensor device according to (1) or (2), in which, in cross-sectional view, each of the grooves disposed in each of the pixels includes the first groove side face and the second groove side face such that the first groove side face and the second groove side face are formed asymmetric with respect to the vertical direction having a reference point on a bottom portion of each of the grooves.

(4)

The sensor device according to any one of (1) to (3), in which, in each of the grooves, a length of the first groove side face and a length of the second groove side face are different from each other in cross-sectional view.

(5)

The sensor device according to any one of (1) to (4),

in which a light collection structure that collects light by using the plural grooves is disposed for each of the pixels, and

plural recessed-projected shapes serving as the light collection structure are formed symmetric with respect to a center of each of the pixels, each of the recessed-projected shapes including a vertical face that is the first groove side face and an inclined face that is the second groove side face and that is inclined such that the further outside from the center of each of the pixels a location of the inclined face is, the larger a depth of a recessed portion corresponding to the inclined face is.

(6)

The sensor device according to (5), in which, for the plural grooves, heights of the recessed-projected shapes are formed approximately uniform.

(7)

The sensor device according to (5), in which, for the plural grooves, heights of the recessed-projected shapes are formed such that the further outside from the center of each of the pixels a location of a recessed-projected shape of interest among the recessed-projected shapes is, the larger a height of the recessed-projected portion of interest is.

(8)

The sensor device according to any one of (5) to (7), further including:

an antireflection film formed along the recessed-projected shapes of the light collection structure of a light receiving face of the semiconductor substrate; and

a protective film formed on the antireflection film such that the protective film is embedded in recessed portions of the light collection structure.

(9)

The sensor device according to any one of (1) to (8), in which a component separation portion for separating adjacent pixels among the pixels is formed in the semiconductor substrate.

(10)

The sensor device according to any one of (1) to (9), further including:

a color filter that is disposed for each of the pixels and configured to transmit light having a color of light to be received by each of the pixels; and

an on-chip lens that is disposed for each of the pixels and configured to collect light to be received by each of the pixels.

(11)

The sensor device according to any one of (5) to (10), in which, in plan view, the light collection structure is formed in a linear shape.

(12)

The sensor device according to any one of (5) to (10), in which, in plan view, the light collection structure is formed in a square shape.

(13)

The sensor device according to any one of (5) to (10), in which, in plan view, the light collection structure is formed in a circular shape.

(14)

The sensor device according to (13), in which the light collection structure is formed in a shape resulting from pupil correction according to an image height.

(15)

The sensor device according to any one of (1) to (10), in which the grooves are formed by performing anisotropic etching of the semiconductor substrate.

(16)

A production method for a production apparatus that produces a sensor device including a semiconductor substrate including a first face on which light is incident and a second face facing opposite to the first face, plural pixels each including a photoelectric conversion region used for performing photoelectric conversion and disposed in the semiconductor substrate, and plural grooves disposed on the first face of each of the pixels, the production method including:

forming, by the production apparatus, the grooves such that, in cross-sectional view, the grooves each include a first groove side face disposed along a vertical direction relative to the second face of the semiconductor substrate and a second groove side face disposed in a direction different from the vertical direction.

(17)

The production method according to (16), in which the grooves are formed by performing anisotropic etching of the semiconductor substrate.

(18)

The production method according to (16), in which the grooves are formed by copying a resist material having been produced by means of nanoimprint onto the semiconductor substrate.

(19)

Electronic equipment including:

a sensor device including
a semiconductor substrate including a first face on which light is incident and a second face facing opposite to the first face,
plural pixels each including a photoelectric conversion region used for performing photoelectric conversion and disposed in the semiconductor substrate, and
plural grooves disposed on the first face of each of the pixels,

in which, in cross-sectional view, the grooves each include a first groove side face disposed along a vertical direction relative to the second face of the semiconductor substrate and a second groove side face disposed in a direction different from the vertical direction.

It should be noted that embodiments of the present disclosure are not limited to the above-described embodiments, and various modifications can be made within the scope not departing from the gist of the present disclosure. Further, the effects described in the present description are just examples and do not limit the effects of the present disclosure, which may have other effects.

### REFERENCE SIGNS LIST

11: Pixel
21: Semiconductor substrate
22: Antireflection film
23: Protective film
24: Light collection structure
25: Wiring layer
26: Component separation portion
27: Color filter
28: On-chip lens
29: Reflective film
30: Reflected light collection structure
31: Image sensing device
32: Package
33: Transparent glass
41: Photoelectric conversion section

1. A sensor device comprising:
a semiconductor substrate including a first face on which light is incident and a second face facing opposite to the first face;
plural pixels each including a photoelectric conversion region used for performing photoelectric conversion and disposed in the semiconductor substrate; and
plural grooves disposed on the first face of each of the pixels,
wherein, in cross-sectional view, the grooves each include a first groove side face disposed along a vertical direction relative to the second face of the semiconductor substrate and a second groove side face disposed in a direction different from the vertical direction.

2. The sensor device according to claim 1, wherein, in cross-sectional view, the plural grooves disposed in each of the pixels each include the first groove side face and the second groove side face such that the grooves are formed line-symmetric with respect to the vertical direction having a reference point on a center portion of each of the pixels.

3. The sensor device according to claim 1, wherein, in cross-sectional view, each of the grooves disposed in each of the pixels includes the first groove side face and the second groove side face such that the first groove side face and the second groove side face are formed asymmetric with respect to the vertical direction having a reference point on a bottom portion of each of the grooves.

4. The sensor device according to claim 1, wherein, in each of the grooves, a length of the first groove side face and a length of the second groove side face are different from each other in cross-sectional view.

5. The sensor device according to claim 1,
wherein a light collection structure that collects light by using the plural grooves is disposed for each of the pixels, and
plural recessed-projected shapes serving as the light collection structure are formed symmetric with respect to a center of each of the pixels, each of the recessed-projected shapes including a vertical face that is the first groove side face and an inclined face that is the second groove side face and that is inclined such that the further outside from the center of each of the pixels a location of the inclined face is, the larger a depth of a recessed portion corresponding to the inclined face is.

6. The sensor device according to claim 5, wherein, for the plural grooves, heights of the recessed-projected shapes are formed approximately uniform.

7. The sensor device according to claim 5, wherein, for the plural grooves, heights of the recessed-projected shapes are formed such that the further outside from the center of the each of the pixels a location of a recessed-projected shape of interest among the recessed-projected shapes is, the larger a height of the recessed-projected shape of interest is.

8. The sensor device according to claim 5, further comprising:
an antireflection film formed along the recessed-projected shapes of the light collection structure of a light receiving face of the semiconductor substrate; and
a protective film formed on the antireflection film such that the protective film is embedded in recessed portions of the light collection structure.

9. The sensor device according to claim 1, wherein a component separation portion for separating adjacent pixels among the pixels is formed in the semiconductor substrate.

10. The sensor device according to claim 1, further comprising:
a color filter that is disposed for each of the pixels and configured to transmit light having a color of light to be received by each of the pixels; and
an on-chip lens that is disposed for each of the pixels and configured to collect light to be received by each of the pixels.

11. The sensor device according to claim 5, wherein, in plan view, the light collection structure is formed in a linear shape.

12. The sensor device according to claim 5, wherein, in plan view, the light collection structure is formed in a square shape.

13. The sensor device according to claim 5, wherein, in plan view, the light collection structure is formed in a circular shape.

14. The sensor device according to claim 13, wherein the light collection structure is formed in a shape resulting from pupil correction according to an image height.

15. The sensor device according to claim 1, wherein the grooves are formed by performing anisotropic etching of the semiconductor substrate.

16. A production method for a production apparatus that produces a sensor device including a semiconductor substrate including a first face on which light is incident and a second face facing opposite to the first face, plural pixels each including a photoelectric conversion region used for performing photoelectric conversion and disposed in the semiconductor substrate, and plural grooves disposed on the first face of each of the pixels, the production method comprising:
forming, by the production apparatus, the grooves such that, in cross-sectional view, the grooves each include a first groove side face disposed along a vertical direction relative to the second face of the semiconductor substrate and a second groove side face disposed in a direction different from the vertical direction.

17. The production method according to claim 16, wherein the grooves are formed by performing anisotropic etching of the semiconductor substrate.

18. The production method according to claim 16, wherein the grooves are formed by copying a resist material having been produced by means of nanoimprint onto the semiconductor substrate.

19. Electronic equipment comprising:
a sensor device including
a semiconductor substrate including a first face on which light is incident and a second face facing opposite to the first face,
plural pixels each including a photoelectric conversion region used for performing photoelectric conversion and disposed in the semiconductor substrate, and
plural grooves disposed on the first face of each of the pixels,
wherein, in cross-sectional view, the grooves each include a first groove side face disposed along a vertical direction relative to the second face of the semiconductor substrate and a second groove side face disposed in a direction different from the vertical direction.
